(19) United States
(12) Patent Application Publication
(10) Pub. No.: US 2008/0266758 A1
(43) Pub. Date: Oct. 30, 2008

(54) MOBILE UTILITIES STATION

(76) Inventor: Steven B. Hurt, Bloomfield Hills, MI (US)

Correspondence Address: CARLSON, GASKEY & OLDS, P.C., 400 WEST MAPLE ROAD, SUITE 350, BIRMINGHAM, MI, 48009, US

(21) Appl. No.: 11/739,767

(22) Filed: Apr. 25, 2007

(51) Int. Cl. H02J 7/00; B60H 1/00; F03D 9/02; H02M 7/00; H01L 31/045

(52) U.S. Cl. 361/625

(57) ABSTRACT

A mobile utilities station includes a plurality of batteries charged by sheets of photovoltaic cells, all mounted in a trailer. The mobile utilities station provides various utilities, for example, electricity, water purification, HVAC, communications, etc. When available sunlight is insufficient to operate all of the devices in use, electricity is supplemented from the batteries. The batteries also power the devices at night. During periods of low usage, the photovoltaic cells recharge the batteries.

### BACKGROUND

The present invention relates generally to a mobile utilities station.

A current mobile utilities station is mounted on a trailer. A diesel engine operating a generator, water filtration system, and environmental conditioning unit (HVAC) are mounted on the frame of the trailer. The unit is compact and portable and can provide basic necessities to disaster areas, such as fire, flood, earthquake or hurricane.

Although the current station works very well in many applications, there are some shortcomings in some particular applications when compared to some of the embodiments of the present invention. The diesel engine must be periodically refilled with fuel for continuous operation. The engine uses fuel inefficiently during periods of low usage or idling. Additionally, the diesel engine will occasionally need maintenance, particularly in windy, sandy locations. In some applications, the noise from the diesel engine is inconvenient. For example, if the unit is providing HVAC and electricity to a communication and organization facility, the noise can make it difficult for the relief workers to communicate within the facility.

### SUMMARY

The present invention provides a mobile utilities station that is powered by renewable energy sources supplying energy to onboard energy storage units. In one embodiment, photovoltaic cells charge a set of batteries on the trailer. The batteries power the onboard utilities, including, for example, HVAC, communications, water purification, lights and a DC to AC inverter that supplies electricity for the users. The mobile utilities station does not need to be refueled and is silent in normal operation. There is also very little maintenance.

Alternatively, or additionally, the unit can include a wind turbine for supplying additional power to the onboard batteries. As another alternative, the renewable energy sources (e.g. solar, wind, etc.) and onboard energy storage (e.g. batteries) could be provided alongside an internal combustion engine (such as the diesel engine provided in the previous station, or a smaller version thereof). The optional internal combustion engine runs only a fraction of the time that was required of the previous station. The engine only needs to run just long enough to recharge the batteries. The engine does not need to run during periods of low usage, which is inefficient. The engine is more efficient at higher usage times and while recharging the batteries.

These and other features of the application can be best understood from the following specification and drawings, the following of which is a brief description.

### BRIEF DESCRIPTION OF THE DRAWINGS

FIG. 1 is a perspective view of a mobile utilities station according to one embodiment of the present invention.

FIG. 2 illustrates the opposite side of the mobile utilities station of FIG. 1.

FIG. 3 is an upper perspective view of the mobile utilities station of FIG. 1.

FIG. 4 is a schematic of an alternate mobile utilities station.

### DETAILED DESCRIPTION OF THE PREFERRED EMBODIMENTS

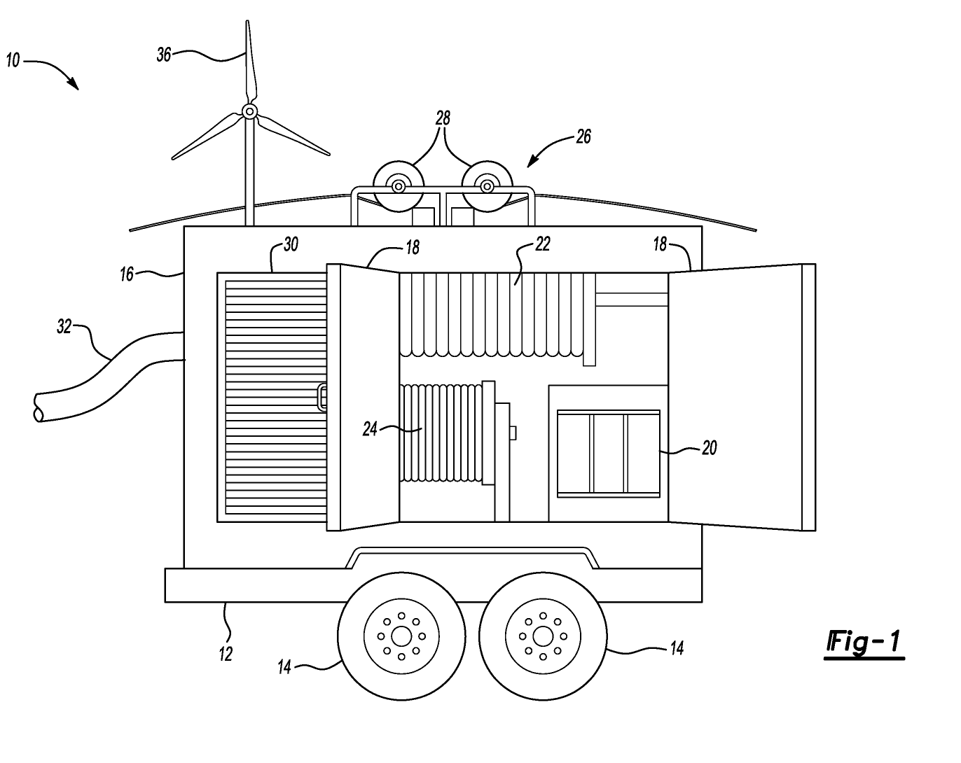

A mobile utilities station 10 according to one embodiment of the present invention is shown in FIG. 1. The mobile utilities station 10 includes a trailer frame 12 having wheels 14. A housing 16 is mounted on the trailer frame 12 and includes access doors 18. Inside the housing 16 is a water purification system 20, which may include various types of filters, water softeners, ultraviolet purification, etc. The water purification system 20 further includes an inlet hose 22 and an outlet hose 24 coiled inside the housing 16.

On top of the housing 16 is a solar power unit 26 having a plurality of rolls 28 of sheets of photovoltaic material (not visible in FIG. 1). Although two rolls 28 are shown, four or more rolls 28 could also be provided.

The mobile utilities station 10 also includes an HVAC system 30. The HVAC system 30 includes an HVAC supply hose 32.

The mobile utilities station 10 may include one or more optional wind turbines 36 (one shown), which can be folded onto the top of the housing 16 during transport and raised for use. The wind turbine 36 generates electricity for the mobile utilities station 10.

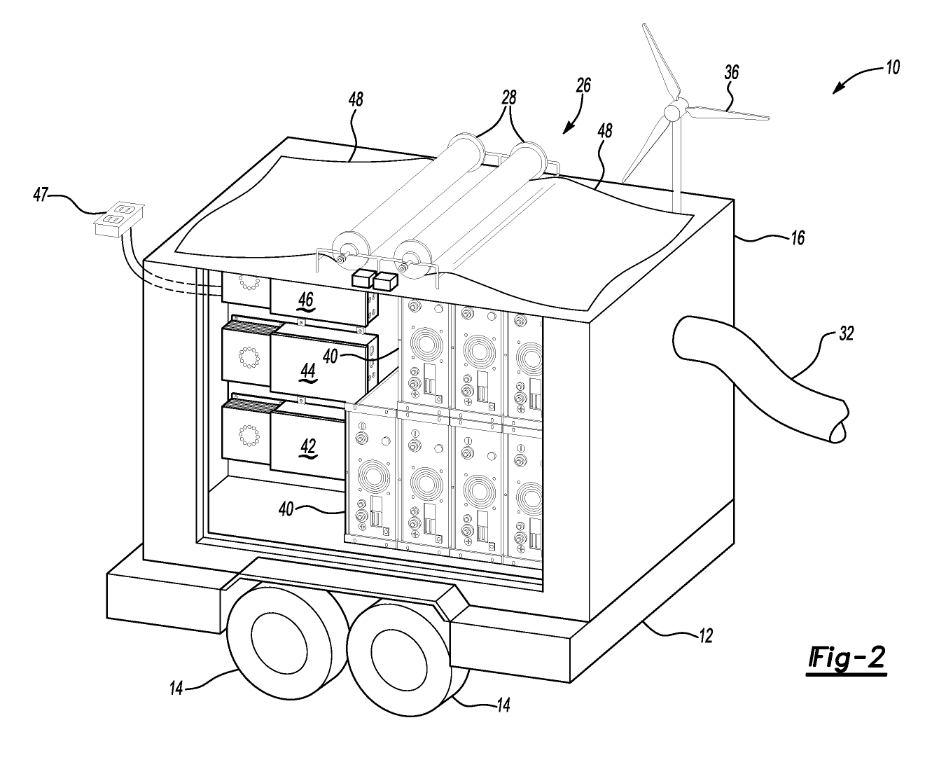

FIG. 2 illustrates the opposite side of the mobile utilities station 10. A plurality of large batteries 40 are secured within the housing 16. Although batteries of many different types and many technologies could be used, in the embodiment shown the batteries 40 are the same type of batteries currently utilized in hybrid vehicles. The number of batteries 40 used depends upon the intended application. If desired, the remaining space in the housing 16 could be filled with the batteries 40.

As is also shown in FIG. 2, the housing 16 also contains electronics 42 for power management, including managing the charging of the batteries 40 and supplying power to the various components from the batteries 40 and from the solar power unit 26 (and any optional power supplies, such as the wind turbine 36), as appropriate, based upon demand and available power at any given time. Satellite communication electronics 44 are also provided for voice and data communications. A DC to AC inverter 46 supplies AC electricity to standard electrical outlets 47 to provide electricity to users for powering electrical tools or other devices.

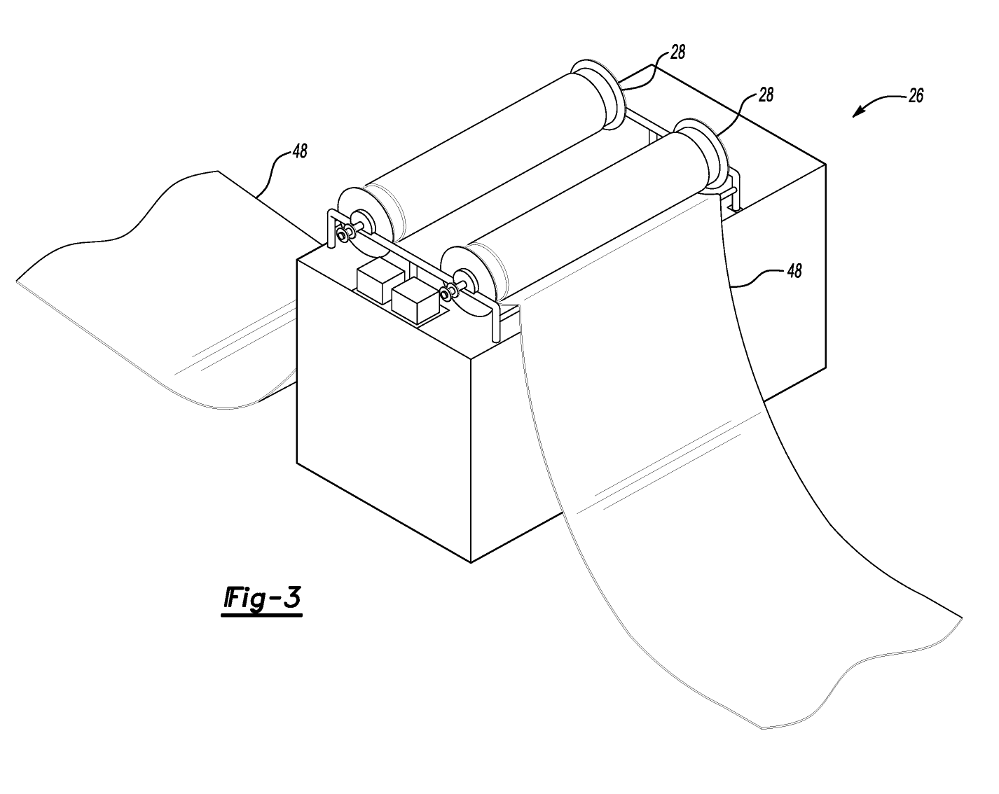

FIG. 3 illustrates the solar power unit 26 in more detail. Sheets 48 of photovoltaic material are rolled around spools 28 during transportation. On site, the sheets 48 are unrolled and extended from the spools 28 on top of the housing 16 to the ground where they are secured. This maximizes the area with which the sheets 48 are receiving sunlight.

In operation, during the day the sheets 48 of photovoltaic cells may supply enough electricity to charge the batteries 40, operate the water purification system 20, power the HVAC system 30, provide additional electricity to the users, and operate the satellite communications 44 (and any other devices). If the sheets 48 of photovoltaic cells do not produce enough electricity to keep up with peak demand, power is supplied simultaneously from both the batteries 40 and from the sheets 48. At night when the sheets 48 are producing no electricity, the batteries 40 supply electricity to the mobile utility station 10 and to the users.

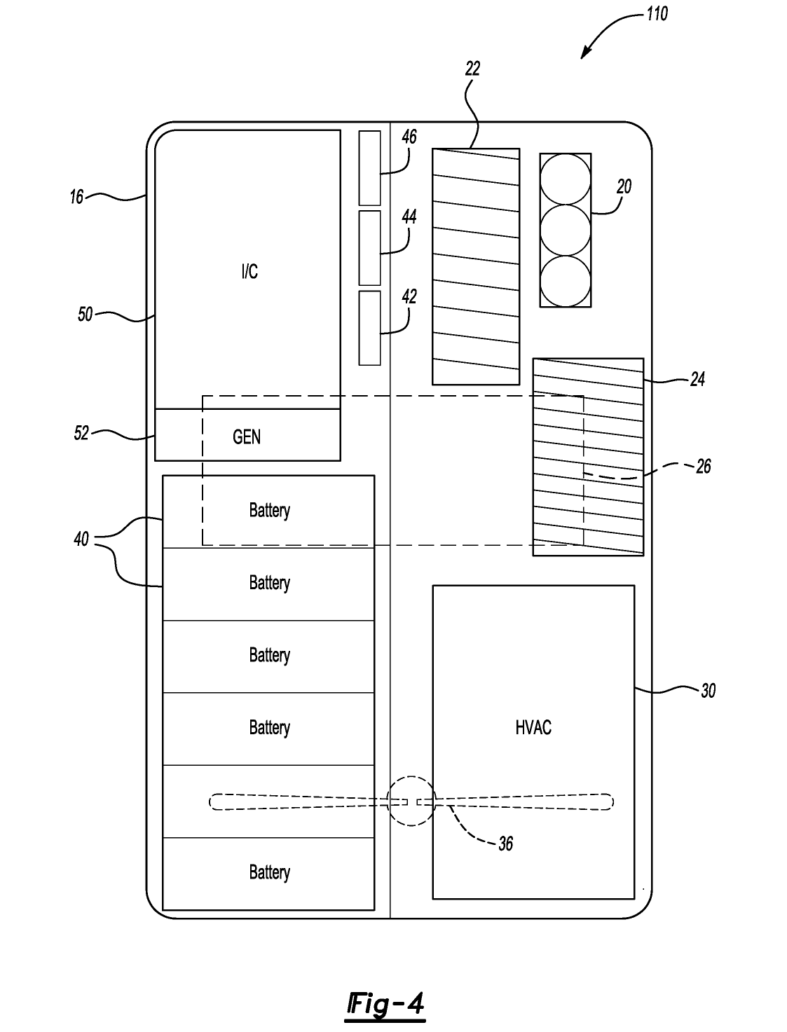

FIG. 4 is a schematic layout of an alternate mobile utilities station 110. Like components are referenced with reference numerals identical to those used in FIGS. 1-3, and are as described as above, except as otherwise stated below. In the mobile utilities station 110 of FIG. 4, an internal combustion engine 50 (such as a gasoline, diesel, bio-diesel, natural gas, hydrogen, propane, etc) with an electricity generator 52 is provided adjacent the batteries 40.

In operation, the power management electronics 42 control operation of the engine 50 and manages power from the generator 52 along with the power from the solar power unit 26 and batteries 40. Since the engine 50 is most efficient at high loads, the engine 50 runs only when the current demand cannot be met by the batteries 40 and the solar power unit 26. When the engine 50 runs, the power from generator 52 supplies the mobile utilities station 110 and also charges the batteries 40. Thus, if usage is otherwise fairly low, but the batteries are drained, the charging of the batteries 40 will ensure that the engine 50 is running at a high load, which is most efficient. The engine 50 runs only long enough to recharge the batteries 40. The engine 50 does not need to run during periods of low usage, which is inefficient.

The power management electronics 42 first uses the power from the renewable sources, such as the solar power unit 26 and optional wind turbine 36. If possible, any extra energy from the renewable sources is used to recharge the batteries 40, if necessary. If the renewable sources are insufficient, power is next drawn from the batteries 40. If the renewable sources 26, 36 and the batteries 40 are insufficient, the engine 50 is started. Whenever the engine 50 is running, the batteries 40 are charged until fully charged, or until the renewable sources 26, 36 are sufficient to meet the current load and begin charging the batteries 40. In many applications, the engine 50 will run a small fraction of the time, which reduces noise, fuel consumption and emissions.

Although an example embodiment has been disclosed, a worker of ordinary skill in this art would recognize that certain modifications would come within the scope of the claims. For that reason, the following claims should be studied to determine their true scope and content.

What is claimed is:

1. A mobile utilities station comprising:
a frame supported by wheels;
at least one battery mounted on the frame; and
a solar cell for charging the battery, the solar cell mounted on the frame.

2. The mobile utilities station of claim 1 further including an HVAC system mounted on the frame and powered by the solar cell and the battery.

3. The mobile utilities station of claim 1 further including a water purification system mounted on the frame.

4. The mobile utilities station of claim 1 wherein the solar cell is a flexible sheet of photovoltaic cells wrapped around a spool mounted to the frame.

5. The mobile utilities station of claim 1 further including an engine powering a generator, the generator configured to recharge the batteries.

6. The mobile utilities station of claim 1 further including an inverter powered by the battery and supplying AC power to an outlet.

7. The mobile utilities station of claim 1 further including a wind turbine generating electricity to charge the battery.

8. A mobile utilities station comprising:
a frame supported by wheels;
at least one battery mounted on the frame;
a solar cell for charging the battery, the solar cell mounted on the frame;
an HVAC system mounted on the frame and powered by the solar cell and the battery; and
an inverter powered by the battery and supplying AC power to an outlet.

9. The mobile utilities station of claim 8 further including a water purification system mounted on the frame.

10. The mobile utilities station of claim 9 wherein the solar cell is a flexible sheet of photovoltaic cells wrapped around a spool mounted to the frame.

11. The mobile utilities station of claim 9 further including an engine powering a generator, the generator configured to recharge the batteries.

12. The mobile utilities station of claim 11 further including a wind turbine generating electricity to charge the battery.

13. The mobile utilities station of claim 11 further including a power management unit controlling the engine and controlling power from the generator, power from the solar cell and power from the battery.

14. The mobile utilities station of claim 13 wherein the power management unit first uses power from the solar cell, then uses power from the battery based upon a determination that power from the solar cell is insufficient.

15. The mobile utilities station of claim 14 wherein the power management unit initiates the engine based upon a determination that sufficient power cannot be drawn from the solar cell and the battery.
